(19) United States
(12) Patent Application Publication
(10) Pub. No.: US 2022/0320708 A1
(43) Pub. Date: Oct. 6, 2022

(54) COMMUNICATION DEVICE

(71) Applicants: Takahiro HOJO, Aichi (JP); Takashi ARAGAI, Aichi (JP); Takanori ISHIGAMI, Aichi (JP); Tetsu ISHIZAKI, Aichi (JP)

(72) Inventors: Takahiro HOJO, Aichi (JP); Takashi ARAGAI, Aichi (JP); Takanori ISHIGAMI, Aichi (JP); Tetsu ISHIZAKI, Aichi (JP)

(73) Assignee: NIDEC MOBILITY CORPORATION, Aichi (JP)

(21) Appl. No.: 17/712,193

(22) Filed: Apr. 4, 2022

(30) Foreign Application Priority Data
Apr. 5, 2021 (JP) 2021-064352

(51) Int. Cl. H01Q 1/12; H01Q 7/00; H05K 1/02

(52) U.S. Cl. CPC H01Q 1/12; H01Q 7/00; H05K 1/0277; H05K 1/0243; H05K 2201/10098

(57) ABSTRACT

A communication device includes a printed circuit board on which a flexible portion configured to be bent is formed. The communication device includes: a first rigid portion provided with a communication circuit; a second rigid portion coupled via one or more flexible portions and provided with an antenna; and a third rigid portion coupled to the first rigid portion via one of the flexible portions and provided with an antenna coupling line configured to electrically couple the communication circuit and the antenna. The antenna coupling line is substantially perpendicular to a board surface of the first rigid portion.

### CROSS-REFERENCE TO RELATED APPLICATIONS

This application is based upon and claims the benefit of priority from Japanese Patent Application No. 2021-064352 filed on Apr. 5, 2021, the entire contents of which are incorporated herein by reference.

### FIELD

One or more embodiments of the present invention relate to a communication device including a printed circuit board.

### BACKGROUND

In the related art, there has been known a communication device where a communication circuit (transmission circuit and/or reception circuit) is provided on a printed circuit board and an antenna is provided in the vicinity of the communication circuit. For example, JP-A-2019-029669 discloses a laminated circuit board that has low loss and facilitates assembly when being coupled to a motherboard or the like. This laminated circuit board is characterized by integrating a ceramic laminated circuit board and a multilayer board including a wiring portion having bending property. For this board, if the board having a flat antenna is mounted such that an antenna surface (surface on a side where the antenna is disposed on the board) is placed on a surface of the motherboard, it is difficult to obtain sufficient radiation characteristics. Therefore, an IC surface (surface on a side where an IC is disposed on the board) is coupled to the motherboard, and it solves a problem that assembly becomes difficult or a structure becomes complicated when securing the coupling with the board.

Further, JP-A-2017-017536 discloses an antenna device capable of increasing the number of turns of an antenna pattern formed on a flexible board at low cost without forming a through-hole. This antenna device includes a flexible board having a first region and a second region, and a magnetic body integrally fixed to a first region and a second region of the flexible board in a state of being folded at a link portion. The first region is formed of a loop-shaped first antenna pattern, and the second region is linked to the first region via the link portion and is folded at the link portion so that a loop-shaped second antenna pattern is formed to be disposed to face the first antenna pattern so as to overlap with each other. In the first region and the second region, coupling portions for electrically coupling the first antenna pattern and the second antenna pattern are provided respectively in a state where a magnetic body sheet is fixed.

Further, WO-A1-2012/036139 discloses an antenna module for a reader/writer that can secure isolation between an antenna conductor and a chip-type component, and protect the chip-type component from external noise and external stress. The antenna module for a reader/writer uses a flexible board having a first base portion, a second base portion, and a bent portion coupling the first base portion and the second base portion. The flexible board has a structure that is folded by utilizing flexibility of the bent portion such that a first main surface of the first base portion and a first main surface of the second base portion face each other. Therefore, in this folded structure, a magnetic body layer is disposed between the antenna conductor and the chip-type component.

Further, JP-A-2017-103691 discloses an antenna device capable of reducing a manufacturing cost of a wiring board without a need to provide a through-hole for forming an antenna pattern over a plurality of layers in a laminated wiring board. This antenna device has a flexible board having an antenna pattern in which a conductor is formed by one layer, an electric component that communicates input/output signals via the antenna pattern, and a connector that electrically couples between the boards. The antenna pattern is provided with a first coupling portion and a second coupling portion. In the first coupling portion, the antenna pattern, a terminal of the electric component, and a terminal of the connector are soldered, and in the second coupling portion, the flexible board is inserted into the connector and electrically coupled to the terminal of the connector, thereby being configured to form a loop antenna.

Further, JP-A-2013-172220 discloses an antenna device that solves deterioration of antenna characteristics. This antenna device includes an antenna board in which a contact point portion to which an antenna connector equipped in a board having a wireless communication circuit is coupled and an antenna wiring coupled to the contact point portion are formed. The antenna board is formed so as to be bendable such that predetermined surfaces face each other, and a loop antenna portion in which a part of the antenna wiring is formed in a loop shape is located on one side of the bent location as a boundary, and a link antenna portion linking the contact point portion and the loop antenna portion of the antenna wiring, and the contact point portion are located on the other side of the bent location as the boundary. The antenna board is formed such that the contact point portion and the loop antenna portion do not have a positional relationship of overlapping each other in a state where the antenna board is bent.

Further, WO-A1-2010/131524 discloses a circuit board or the like capable of more accurately matching impedance between an antenna coil and an electronic component electrically coupled to the antenna coil. In this circuit board, a board main body has two board portions, and a plurality of insulator layers made of a flexible material is laminated. The antenna coil is configured of a coil conductor provided on a first board portion. The wiring conductor is provided on a second board portion and is electrically coupled to the antenna coil. The second board portion has a configuration that is less likely to be deformed than configuration of the first board portion. An integrated circuit electrically coupled to a wiring conductor is mounted on the second board portion.

Further, JP-A-2014-014030 discloses an antenna device realizing a structure in which a linear antenna can stably stand on a circuit board even before being fixed to the circuit board by soldering, and which is simplified for assembly. In this antenna device, the linear antenna includes an antenna main body portion bridged in a space on the circuit board and two leg portions standing on the circuit board to support the antenna main body. Further, the linear antenna includes two insertion portions fixed to the circuit board by solder in a state of obliquely penetrating an antenna mounting hole of the circuit board. Each of the two insertion portions is formed so as to extend in an oblique direction with respect to a thickness direction of the circuit board from each of the two folded portions folded in opposite directions in each of regions between portions of the leg portions being in contact with edge portions on both sides of the antenna mounting hole.

Although it is not related to a communication device, there are the following prior arts related to a flexible board. For example, JP-A-2019-091789 discloses a circuit board in which the folding reliability of a folded portion is improved while securing the number of wiring layers. This flexible wiring board is provided with a two-layer wiring structure, a rigid board is provided with an M-layer (M is an integer of 3 or more) wiring structure, a glass epoxy resin is used as a base material for the flexible wiring board and the rigid board, a thickness of the flexible wiring board is set in a range of 110 μm to 190 μm, and the flexible wiring board can be folded by 180 degrees or more five times or more.

Further, JP-A-2018-182215 discloses a manufacturing method of a rigid and flex multilayer printed wiring board in which cracking of a base material of a flexible board portion is suppressed even if a router bit machined line (groove) is formed on a cut surface when the flexible board portion is machined to a thickness that can be folded by cutting. This manufacturing method is a manufacturing method of the rigid and flex multilayer printed wiring board in which a resin-impregnated glass cloth is used for the insulating base material of the rigid board portion and the insulating base material of the flexible board portion. This manufacturing method has a step of forming the flexible board portion by moving a router in a direction orthogonal to the folding line of the flexible board portion while operating the router, and cutting the insulating base material of the flexible board portion to a foldable thickness by a drill bit of the router. In addition, JP-A-2002-158445 also relates to a flexible board.

### SUMMARY

One or more embodiments of the present invention provide a communication device including a printed circuit board, in which an efficiency of an antenna is improved, the number of components is reduced, and assembly is facilitated.

In one or more embodiments of the present invention, there is provided a communication device including a printed circuit board on which a flexible portion configured to be bent is formed, the communication device including: a first rigid portion provided with a communication circuit; a second rigid portion coupled via one or more flexible portions and provided with an antenna; and a third rigid portion coupled to the first rigid portion via one flexible portion and provided with an antenna coupling line configured to electrically couple the communication circuit and the antenna, in which the antenna coupling line is substantially perpendicular to a board surface of the first rigid portion.

With this configuration, it is possible to provide the communication device including the printed circuit board in which the efficiency of the antenna is improved, the number of components is reduced, and assembly is facilitated by making the antenna coupling line provided in the third rigid portion coupled to the first rigid portion, which is provided with the communication circuit, via the flexible portion be substantially perpendicular to the board surface of the first rigid portion.

Further, the board surface of the first rigid portion and a board surface of the second rigid portion may be substantially parallel to each other.

With this configuration, since the board surfaces of the first rigid portion and the second rigid portion are substantially parallel to each other, it is possible to provide a compact communication device.

Further, the antenna may be provided on a board surface of the second rigid portion which is far from the board surface of the first rigid portion.

With this configuration, the efficiency of the antenna can be improved by providing the antenna on the board surface far from the first rigid portion.

Further, the communication circuit may be provided on a board surface of the first rigid portion which is closer to the board surface of the second rigid portion.

With this configuration, since the communication circuit is provided on the board surface closer to the second rigid portion, it is possible to provide a compact communication device.

Further, the communication device may further include a housing that accommodates the printed circuit board, in which a length of the third rigid portion in a direction in which the flexible portion is linearly formed may be shorter than a length of the first rigid portion and a length of the second rigid portion in the direction in which the flexible portion is linearly formed, and an inner wall of the housing may be provided with grooves configured to receive edges of the first rigid portion and the second rigid portion in a direction perpendicular to the direction in which the flexible portion is linearly formed.

With this configuration, the length of the third rigid portion in the direction in which the flexible portion is linearly formed is shorter than the length of the first rigid portion and the length of the second rigid portion, and the inner wall of the housing is provided with the grooves for receiving the edges of the first rigid portion and the second rigid portion, so that it is possible to provide a communication device that is easy to assemble.

Further, the communication device may further include a housing that accommodates the printed circuit board, in which the first rigid portion may be formed to have a length in a direction perpendicular to a direction in which the flexible portion is linearly formed to be longer than that of the second rigid portion, and a first screw hole is provided in a portion of the first rigid portion which is formed longer than the second rigid portion, the first rigid portion may be formed to have a length in the direction in which the flexible portion is linearly formed shorter than that of the second rigid portion, and a second screw hole is provided in a portion of the second rigid portion, which is formed longer than the first rigid portion and screw holes conforming to the first screw hole and the second screw hole may be provided on an inner wall of the housing.

With this configuration, the first screw hole is provided in the portion where the length of the first rigid portion is formed longer than the length of the second rigid portion in the direction perpendicular to the direction in which the flexible portion is linearly formed, the length of the first rigid portion is formed shorter than the length of the second rigid portion in the direction in which the flexible portion is linearly formed, the second screw hole is provided in the portion of the second rigid portion, which is formed longer than the first rigid portion, and the screw holes conforming to the first screw hole and the second screw hole are provided on the inner wall of the housing, so that it is possible to provide a communication device that is easy to assemble.

Further, the third rigid portion may include a terminal electrically coupled to the communication circuit.

With this configuration, the third rigid portion has the terminal electrically coupled to the communication circuit, so that it is possible to easily transmit and receive signals to and from an external element.

As described above, according to one or more embodiments of the present invention, it is possible to provide a communication device including a printed circuit board, in which the efficiency of the antenna is improved, the number of components is reduced, and assembly is facilitated.

### BRIEF DESCRIPTION OF DRAWINGS

FIGS. 1A, 1B, and 1C are respectively a top view, a bottom view, and a side view of a communication device according to a first embodiment of the present invention;

FIGS. 2A and 2B are respectively a perspective view after bending and a schematic side view after bending of the communication device according to the first embodiment of the present invention;

FIGS. 3A and 3B are respectively a perspective view in a case where the communication device according to the first embodiment of the present invention is accommodated in a housing and a perspective view in a case where the same has been accommodated in the housing;

FIG. 4 is a perspective view of a case where the communication device according to the first embodiment of the present invention is accommodated in the housing;

FIG. 5 is a perspective view of a case where a communication device according to Modified Example 1 of the first embodiment of the present invention is accommodated in a housing;

FIGS. 6A and 6B are respectively a perspective view after bending of a communication device according to Modified Example 2 of the first embodiment of the present invention, and a front view of a housing for accommodating the same;

FIGS. 7A, 7B, and 7C are respectively a top view, a bottom view, and a side view of a communication device according to a second embodiment of the present invention; and

FIG. 8 is a perspective view after bending of the communication device according to the second embodiment of the present invention.

### DETAILED DESCRIPTION

In embodiments of the invention, numerous specific details are set forth in order to provide a thorough understanding of the invention. However, it will be apparent to one of ordinary skill in the art that the invention may be practiced without these specific details. In other instances, well-known features have not been described in detail to avoid obscuring the invention.

Hereinafter, each embodiment of a communication device according to the present invention will be described with reference to the drawings.

### First Embodiment

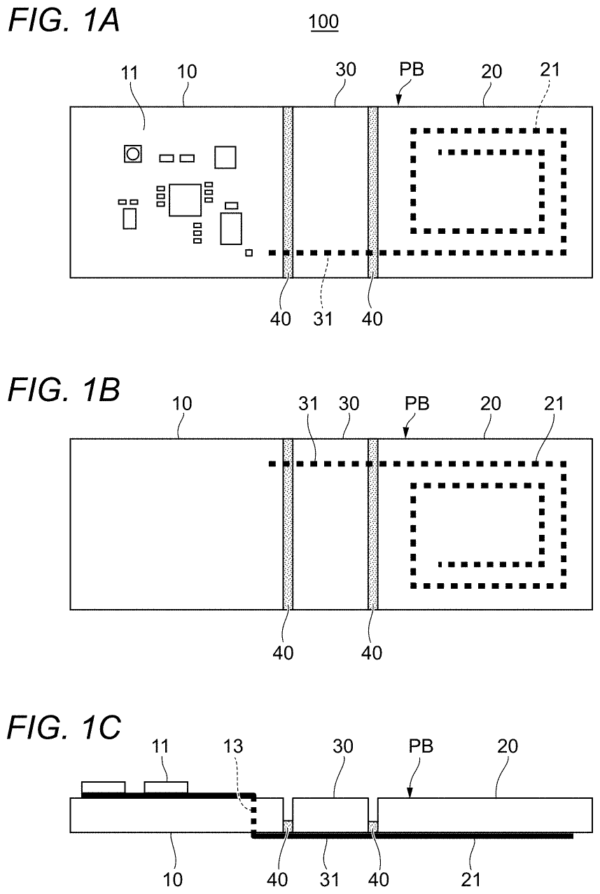

A communication device 100 in the present embodiment will be described with reference to FIGS. 1A to 4. FIGS. 1A, 1B, and 1C illustrate a flat plate-shaped state before the communication device 100 is bent. The communication device 100 is a communication device including a printed circuit board PB. The printed circuit board PB is formed in which conductor wiring is applied on or inside an insulator board, and an electronic component constituting a communication circuit 11 is attached to a board by soldering. As described in detail below, the printed circuit board PB is including a flexible portion 40 that can be bent and flat plate-shaped rigid portions 10/20/30 that cannot be bent.

The flexible portions 40 are formed by being sandwiched between the rigid portions 10/20/30, and the communication device 100 can be three-dimensionally configured by being folded by the flexible portions 40. The rigid portions 10/20/30 are rigid portions having a hardness and a strength that can withstand a weight of the mounted electronic component and can be fixed to a housing 200. Since the flexible portion 40 is a flexible portion having flexibility in which folding can be provided and is a part of the printed circuit board PB, conductor wiring is provided on the surface and inside, and the flexible portion 40 has a function of electrically coupling the rigid portions 10/20/30 on both sides.

A method of forming the flexible portion 40 and the rigid portions 10/20/30 is not particularly limited. For example, the printed circuit board PB may be formed by superimposing a flexible base material made of polyimide or the like and a rigid base material having no flexibility, and the flexible portion 40 may be formed by scraping the rigid base material (rigid layer) so as to leave only the flexible base material (flexible layer) later. Further, the flexible portion 40 may be formed by forming the printed circuit board PB only with the rigid base material and scraping the rigid base material until a thickness to be bendable.

The communication device 100 includes the first rigid portion 10 provided with the communication circuit 11, the second rigid portion 20 provided with a loop antenna 21, and the third rigid portion 30 provided with an antenna coupling line 31 that electrically couples the communication circuit 11 and the loop antenna 21. The communication device 100 has one linear flexible portion 40 between the first rigid portion 10 and the third rigid portion 30, and one linear flexible portion 40 between the third rigid portion 30 and the second rigid portion 20. Therefore, the third rigid portion 30 is coupled to the first rigid portion 10 via one flexible portion 40, and the second rigid portion 20 is coupled to the first rigid portion 10 via two flexible portions 40.

In the communication device 100, the third rigid portion 30 is provided next to the first rigid portion 10, and the second rigid portion 20 is provided next to the third rigid portion 30 in a direction opposite to the first rigid portion 10, but not limited to this. For example, the second rigid portion 20 may be coupled via three flexible portions 40. That is, another rigid portion may be provided between the second rigid portion 20 and the third rigid portion 30, and coupled to the first rigid portion 10 via these. Further, in the present embodiment, the second rigid portion 20 is provided in the direction opposite to the first rigid portion 10 (on a right side of the third rigid portion 30 in the view in FIG. 1A) with the third rigid portion 30 interposed therebetween. However, it may be provided on an upper side or a lower side of the third rigid portion 30 in the view (in the same drawing). A width of the flexible portion 40 is appropriately determined from a thickness and a folding angle of the printed circuit board PB.

The first rigid portion 10 has the communication circuit 11 mounted on an upper surface side (FIG. 1A). The communication circuit 11 may be only a transmission circuit, be only a reception circuit, be provided with both the transmission circuit and the reception circuit, and be appropriately configured of an IC chip including these circuits. The first rigid portion 10 does not have a circuit on a bottom surface side (FIG. 1B), but is provided with a through-hole 13 for electrically coupling the upper surface side and the bottom surface side (FIG. 1C). The upper surface side of the first rigid portion 10 on which the communication circuit 11 is mounted is inside in a case where the printed circuit board PB is bent by the two flexible portions 40 to assemble the communication device 100.

The second rigid portion 20 has the loop antenna 21 provided as conductor wiring on the board surface on the bottom surface side (FIG. 1B). The loop antenna 21 improves the antenna efficiency because the conducting wire is looped and excited from a gap between them. The antenna provided in the second rigid portion 20 is not limited to the loop antenna, and it is sufficient that an antenna length corresponding to a desired frequency/wavelength such as an S-shaped antenna or an L-shaped antenna can be secured. The bottom surface side of the second rigid portion 20 on which the loop antenna 21 is mounted is outside in a case where the printed circuit board PB is bent by the two flexible portions 40 to assemble the communication device 100.

The third rigid portion 30 has the antenna coupling line 31 provided as conductor wiring on the board surface on the bottom surface side (FIG. 1B). The antenna coupling line 31 is electrically coupled to the communication circuit 11 via the flexible portion 40 on one side (left side in the drawing) and the through-hole 13. Further, the antenna coupling line 31 is electrically coupled to the loop antenna 21 via the other flexible portion 40 (right side in the drawing). The communication circuit 11, the antenna coupling line 31, and the loop antenna 21 are electrically coupled in series. The antenna coupling line 31 is wired so as to be perpendicular to the flexible portion 40.

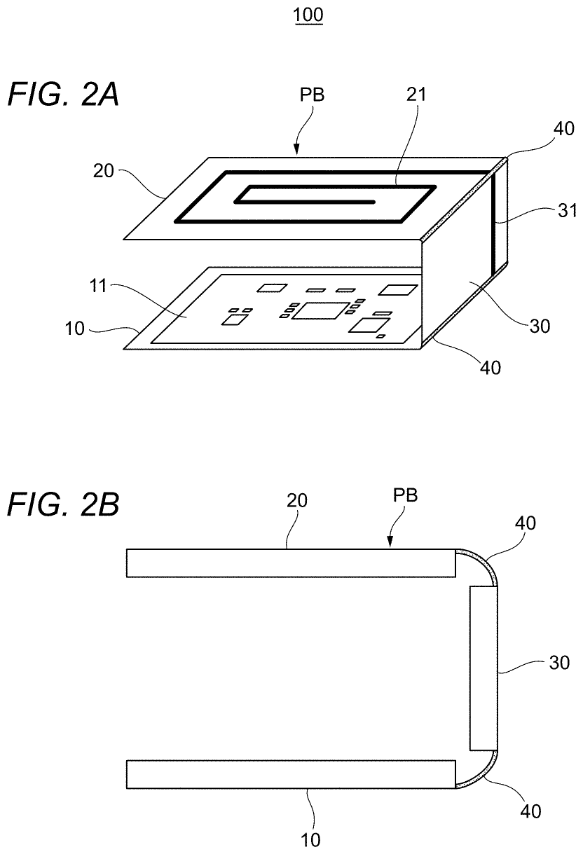

As illustrated in FIG. 2A, the communication device 100 is formed by folding the printed circuit board PB on the flat plate illustrated in FIGS. 1A to 1C by two flexible portions 40 respectively at an angle of 90 degrees. As a result of folding, the board surface of the third rigid portion 30 is substantially perpendicular to the board surface of the first rigid portion 10, and the board surface of the second rigid portion 20 is substantially perpendicular to the board surface of the third rigid portion 30 and is substantially parallel to the board surface of the first rigid portion 10. Thereby, it is possible to provide the compact communication device 100. Further, the board surface of the third rigid portion 30 is substantially perpendicular to the board surface of the first rigid portion 10, so that the antenna coupling line 31 is substantially perpendicular to the board surface of the first rigid portion 10.

Therefore, the antenna coupling line 31 functions as a monopole antenna with the board surface of the first rigid portion 10 as a ground plate. In this way, the antenna coupling line 31 provided in the third rigid portion 30 coupled via the flexible portion 40 to the first rigid portion 10 provided with the communication circuit 11 is substantially perpendicular to the board surface of the first rigid portion 10. Therefore, it is possible to provide the communication device 100 in which the efficiency of the antenna is improved and the need for another component is eliminated, thereby reducing the number of components and facilitating assembly. In the present embodiment, the flexible portion 40 is formed so as to be located outside the folded portion as illustrated in FIG. 2B, but is not limited to this, and may be formed so as to be located inside.

As illustrated in FIG. 2A, the loop antenna 21 is provided on the outside (upper side in the drawing) of the second rigid portion 20, that is, on the board surface far from the board surface of the first rigid portion 10. This makes it easier to transmit and receive electric waves to and from the outside of the communication device 100, and the efficiency of the antenna can be improved. Further, the communication circuit 11 is provided on the inside (upper side in the drawing) of the first rigid portion 10, that is, on the board surface closer to the board surface of the second rigid portion 20. Thereby, it is possible to provide the compact communication device 100 where the communication circuit 11 can be accommodated in the inner space.

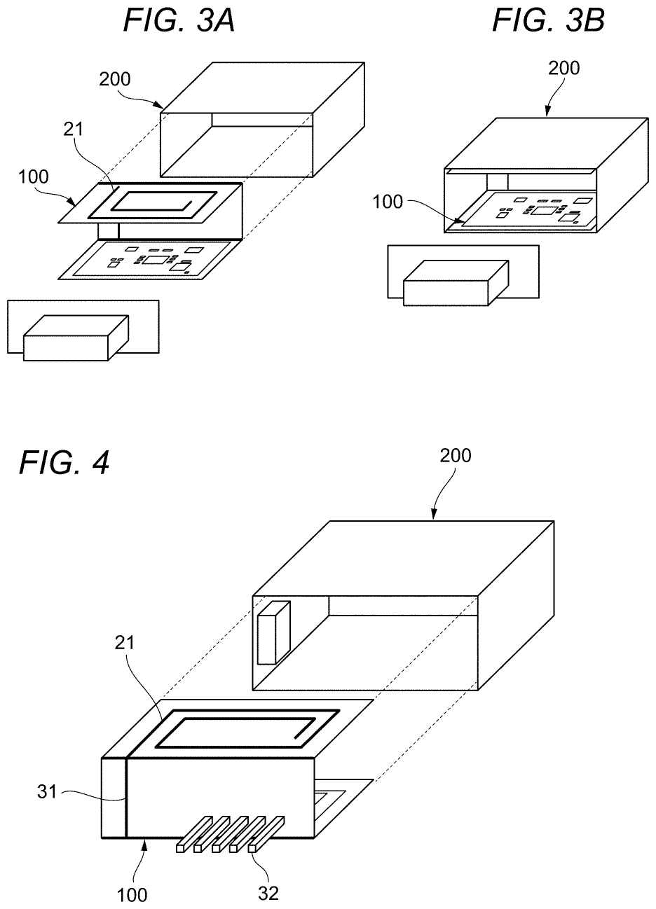

As illustrated in FIGS. 3A and 3B, the communication device 100 is accommodated in the housing 200 in the folded state as illustrated in FIG. 2A. In the present embodiment, the first rigid portion 10 is assembled by sliding the inside of the bottom surface of the housing 200 so that the third rigid portion 30 is on the back side and the loop antenna 21 is on the upper surface. After that, the communication device 100 is completed by closing a lid of the housing 200. As illustrated in FIG. 4, in a case where the third rigid portion 30 has a terminal 32 electrically coupled to the communication circuit 11, it is preferable to assemble the first rigid portion 10 by sliding the inside of the bottom surface of the housing 200 such that the third rigid portion 30 is on the front side and the loop antenna 21 is on the upper surface. It is possible to easily transmit and receive signals to and from an external element by providing a terminal hole (not illustrated) in the lid of the housing 200.

### Modified Example 1 of First Embodiment

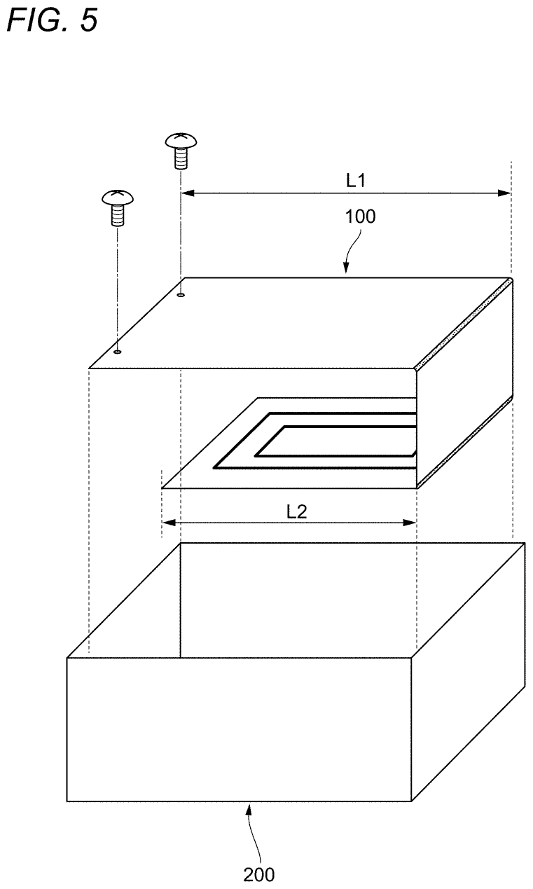

Modified Example 1 in the present embodiment will be described with reference to FIG. 5. A communication device 100 of Modified Example 1 is the same as that of the above-described embodiment in that a first rigid portion 10 provided with a communication circuit 11, a second rigid portion 20 provided with a loop antenna 21, and a third rigid portion 30 provided with an antenna coupling line 31 which electrically couples the communication circuit 11 and the loop antenna 21 are provided. The difference is that in the above-described embodiment, the sizes of the first rigid portion 10 and the second rigid portion 20 are substantially the same, but they are different. That is, in a direction perpendicular to the direction in which a flexible portion 40 is linearly formed, a length L1 of the first rigid portion 10 is formed longer than a length L2 of the second rigid portion 20. Therefore, a first screw hole (not illustrated) can be provided in a portion of the first rigid portion 10 that is longer than the second rigid portion 20. Further, by providing a screw hole conforming to the first screw hole on the inner wall of the housing 200, it is possible to provide the communication device 100 that is easy to assemble.

Further, preferably, the length of the first rigid portion 10 may be formed shorter than the length of the second rigid portion 20 in the direction in which the flexible portion 40 is linearly formed. Therefore, a second screw hole (not illustrated) can be provided in the portion of the second rigid portion 20 that is longer than the first rigid portion 10. Further, by providing a screw hole conforming to the second screw hole on the inner wall of the housing 200, it is possible to provide the communication device 100 that is easy to assemble.

### Modified Example 2 of First Embodiment

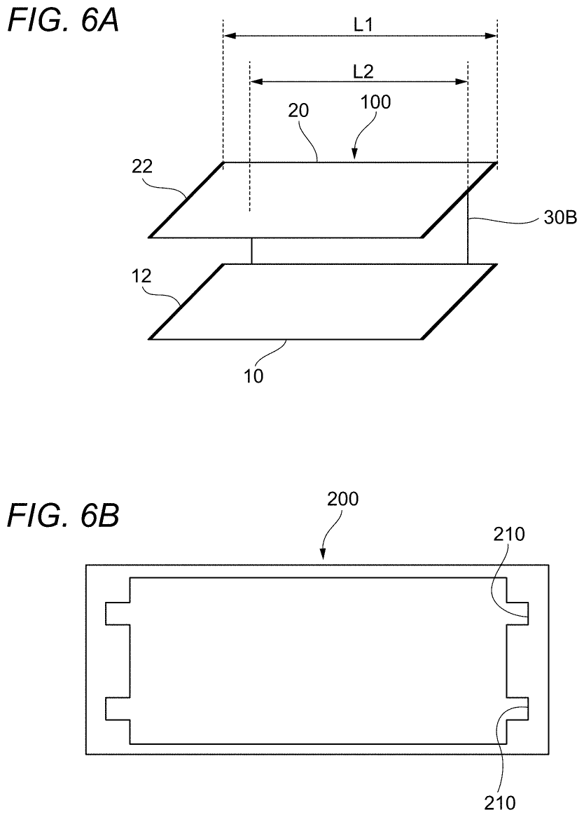

Modified Example 2 in the present embodiment will be described with reference to FIGS. 6A and 6B. A communication device 100 of Modified Example 2 is the same as that of the above-described embodiment in that a first rigid portion 10 provided with a communication circuit 11, a second rigid portion 20 provided with a loop antenna 21, and a third rigid portion 30B provided with an antenna coupling line 31 which electrically couples the communication circuit 11 and the loop antenna 21 are provided. The difference is that in the above-described embodiment, the lengths of the first rigid portion 10 and the second rigid portion 20 (in the view of the drawing), and the length of the third rigid portion 30B are substantially the same, but they are different. That is, a length L2 of the third rigid portion 30B in a direction in which the flexible portion 40 is linearly formed is formed shorter than a length L1 of the first rigid portion 10 and the second rigid portion 20 in the direction in which the flexible portion 40 is linearly formed. Further, the inner wall of the housing 200 is provided with a groove 210 for receiving an edge 12 of the first rigid portion 10 and an edge 22 of the second rigid portion 20 in a direction perpendicular to the direction in which the flexible portion 40 is linearly formed. The edge 12 and the edge 22 are fitted into grooves 210 and slid to be assembled such that the third rigid portion 30B is on the back side and the loop antenna 21 is on the upper surface.

As described above, in the direction in which the flexible portion 40 is linearly formed, the length of the third rigid portion 30B is shorter than the length of the first rigid portion 10 and the length of the second rigid portion 20, and the inner wall of the housing 200 is provided with grooves 210 for receiving the edge 12 of the first rigid portion 10 and the edge 22 of the second rigid portion 20, so that it is possible to provide the communication device 100 that is easy to assemble.

### Second Embodiment

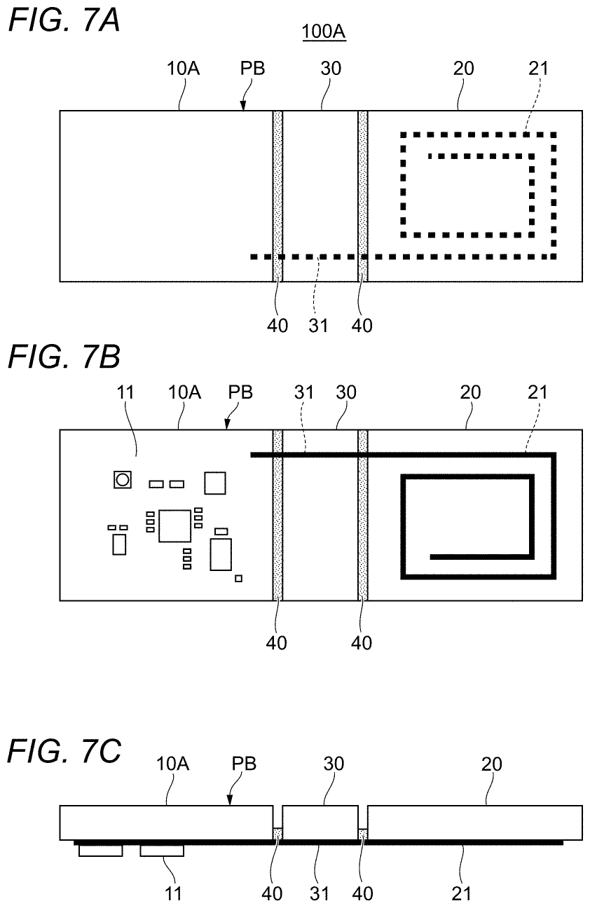

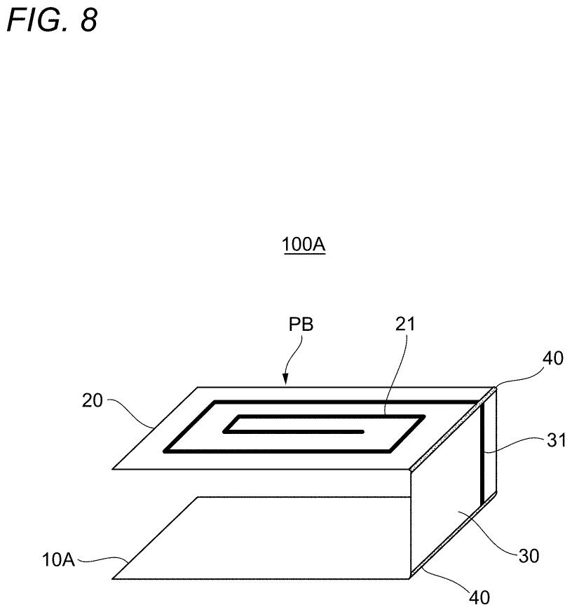

A communication device 100A in the present embodiment will be described with reference to FIG. 7A to FIG. 8. In addition, in order to avoid duplicate description, the same configuration elements as those in the above-described embodiment are designated by the same reference numerals, and the description thereof will be omitted. A communication device 100A is a communication device including a printed circuit board PB. The communication device 100A includes a first rigid portion 10A provided with a communication circuit 11, a second rigid portion 20 provided with a loop antenna 21, and a third rigid portion 30 provided with an antenna coupling line 31 that electrically couples the communication circuit 11 and the loop antenna 21.

Since the communication circuit 11 is mounted on the bottom surface side (FIG. 7B) of the first rigid portion 10A on the same side as the loop antenna 21 of the second rigid portion 20, the through-hole 13 provided in the above-described embodiment is not provided because it is not necessary. The bottom surface side of the first rigid portion 10A on which the communication circuit 11 is mounted is outside in a case where the printed circuit board PB is bent by the two flexible portions 40 to assemble the communication device 100A.

The second rigid portion 20 has the loop antenna 21 provided as conductor wiring on the board surface on the bottom surface side (FIG. 7B). The bottom surface side of the second rigid portion 20 on which the loop antenna 21 is mounted is outside in a case where the printed circuit board PB is bent by the two flexible portions 40 to assemble the communication device 100A.

The third rigid portion 30 has the antenna coupling line 31 provided as conductor wiring on the board surface on the bottom surface side (FIG. 7B) thereof. The antenna coupling line 31 is electrically coupled to the communication circuit 11 via the flexible portion 40 on one side (left side in the drawing) and electrically coupled to the loop antenna 21 via the flexible portion 40 on the other side (right side in the drawing). The communication circuit 11, the antenna coupling line 31, and the loop antenna 21 are electrically coupled in series on the outside in a case where the communication device 100A is assembled. The antenna coupling line 31 is wired so as to be perpendicular to the flexible portion 40.

As illustrated in FIG. 8, the communication device 100A is formed by folding the printed circuit board PB on the flat plate illustrated in FIGS. 7A, 7B, and 7C at an angle of 90 degrees at each of the two flexible portions 40. As a result of folding, the board surface of the third rigid portion 30 is substantially perpendicular to the board surface of the first rigid portion 10A, and the board surface of the second rigid portion 20 is substantially parallel to the board surface of the first rigid portion 10A. Thereby, it is possible to provide the compact communication device 100A. However, since the communication circuit 11 is located on the outside in a case of being assembled, a space for accommodating the communication circuit 11 is required between the first rigid portion 10A and the housing 200 in a case where the communication circuit 11 is accommodated in the housing 200.

Further, the board surface of the third rigid portion 30 is substantially perpendicular to the board surface of the first rigid portion 10A, so that the antenna coupling line 31 is substantially perpendicular to the board surface of the first rigid portion 10A. Therefore, the antenna coupling line 31 functions as a monopole antenna with the board surface of the first rigid portion 10A as a ground plate. As described above, the antenna coupling line 31 provided in the first rigid portion 10A provided with the communication circuit 11 and the third rigid portion 30 coupled via the flexible portion 40 is substantially perpendicular to the board surface of the first rigid portion 10A. Therefore, it is possible to provide the communication device 100A in which the efficiency of the antenna is improved and the need for another component is eliminated, thereby reducing the number of components and facilitating assembly.

It should be noted that the present invention is not limited to the illustrated embodiments, and can be implemented with a configuration within a range that does not deviate from the contents described in each section of the claims. That is, the present invention is mainly illustrated and described with respect to particular embodiments, but without departing from the scope of the technical idea and object of the present invention, in the quantity and other detailed configurations with respect to the above-described embodiments, those skilled in the art can make various modifications.

While the invention has been described with respect to a limited number of embodiments, those skilled in the art, having benefit of this disclosure, will appreciate that other embodiments can be devised which do not depart from the scope of the invention as disclosed herein. According, the scope of the invention should be limited only by the attached claims.

1. A communication device comprising a printed circuit board on which a flexible portion configured to be bent is formed, the communication device comprising:
a first rigid portion provided with a communication circuit;
a second rigid portion coupled via one or more flexible portions and provided with an antenna; and
a third rigid portion coupled to the first rigid portion via one flexible portion and provided with an antenna coupling line configured to electrically couple the communication circuit and the antenna,
wherein the antenna coupling line is substantially perpendicular to a board surface of the first rigid portion.

2. The communication device according to claim 1,
wherein the board surface of the first rigid portion and a board surface of the second rigid portion are substantially parallel to each other.

3. The communication device according to claim 2,
wherein the antenna is provided on a board surface of the second rigid portion which is far from the board surface of the first rigid portion.

4. The communication device according to claim 2,
wherein the communication circuit is provided on a board surface of the first rigid portion which is closer to the board surface of the second rigid portion.

5. The communication device according to claim 2, further comprising:
a housing that accommodates the printed circuit board,
wherein a length of the third rigid portion in a direction in which the flexible portion is linearly formed is shorter than a length of the first rigid portion and a length of the second rigid portion in the direction in which the flexible portion is linearly formed, and
an inner wall of the housing is provided with grooves configured to receive edges of the first rigid portion and the second rigid portion in a direction perpendicular to the direction in which the flexible portion is linearly formed.

6. The communication device according to claim 2, further comprising:
a housing that accommodates the printed circuit board,
wherein the first rigid portion is formed to have a length in a direction perpendicular to a direction in which the flexible portion is linearly formed to be longer than that of the second rigid portion, and a first screw hole is provided in a portion of the first rigid portion which is formed longer than the second rigid portion,
wherein the first rigid portion is formed to have a length in the direction in which the flexible portion is linearly formed to be shorter than that of the second rigid portion, and a second screw hole is provided in a portion of the second rigid portion which is formed longer than the first rigid portion, and
wherein screw holes conforming to the first screw hole and the second screw hole are provided on an inner wall of the housing.

7. The communication device according to claim 2,
wherein the third rigid portion comprises a terminal electrically coupled to the communication circuit.
